(19) United States
(12) Patent Application Publication
(10) Pub. No.: US 2026/0223278 A1
(43) Pub. Date: Jul. 30, 2026

(54) FLEXIBLE DIAPHRAGM VAPOUR CHAMBER HEAT SINK ASSEMBLY

(71) Applicant: Ciena Corporation, Hanover, MD (US)

(72) Inventors: Peter Ajersch, Ottawa (CA); Trevor Meunier, Kemptville (CA)

(21) Appl. No.: 19/038,941

(22) Filed: Jan. 28, 2025

(51) Int. Cl. H05K 1/02

(52) U.S. Cl. CPC H05K 1/0203

(57) ABSTRACT

A flexible diaphragm vapour chamber heat sink assembly including a vapour chamber heat sink including a rigid outer surface and a flexible device surface coupled together and separated to form a vapour chamber space there between, where the flexible device surface is adapted to be disposed adjacent to and in thermal contact with a device and/or die disposed on a printed circuit board. In some embodiments, the flexible diaphragm vapour chamber heat sink assembly further includes a plurality of partial pillars and/or spring members disposed between and coupled to one of the flexible device surface and the rigid outer surface, where the plurality of partial pillars and/or spring members are disposed within the vapour chamber space proximate the device and/or die and adapted to limit and/or control compression of the vapour chamber space when the device and/or die deflect the flexible device surface.

### TECHNICAL FIELD

The present disclosure relates generally to the telecommunications and networking fields. More particularly, the present disclosure relates to a flexible diaphragm vapour chamber heat sink assembly for cooling a device disposed on a printed circuit board (PCB).

### BACKGROUND

Two types of heat sink attachments are generally considered when implementing heat sinks in a circuit assembly.

One configuration is a “table top heat sink” which is of solid construction including a heat sink base (the “table surface”) with heat sink fins extended into the adjacent air path and four stubby “table legs” extended to meet the PCB. This type of heat sink is hard-connected to the PCB, typically screwed down such that the heat sink bears down on the PCB via the legs. In this configuration, one must allow for a gap between the device top and the underside of the heat sink base so that the device is not crushed. When considering the dimensional tolerance loop, one must build in a gap on the order of ~1 mm, and one must fill this gap with a thermal pad or a thermal gel to thermally bridge the heat from the device to the heat sink. Because of the thickness of the gap—and the thermal interface material (TIM) that fills the gap—such a configuration may be thermally limited. As such, it is unlikely for one to use this setup for a 100 W device.

Another configuration is a “sprung heat sink” in which the heat sink attachment allows the heat sink to float in space such that it is unimpeded in bearing down against the device top. In this configuration, one uses a very thin TIM (in fact, preferably the thinnest TIM practically available), such as a grease or phase change material that squeezes down to a thickness on the order of ~0.1 mm. The heat sink attachment is a sub-assembly of screws and springs that are arranged in manner that drives the heat sink base against the device on the PCB with some intended force. This configuration is good thermally, but because the heat sink must be free to move (toward and against the device top), the configuration is less robust mechanically than the “table top” configuration.

Known solutions make use of a rigid vapour chamber design that uses compression springs at the mounting points, like the “sprung heat sink: configuration. This configuration takes up design tolerance and applies sufficient force to the device on the PCB for the phase change TIM to perform within specifications.

These existing solutions are complex, take up significant real estate (physical volume) in a design, and have large tolerance loops. Multiple moving parts make these designs more prone to assembly and functional issues and current products are very limited in useable space—the less extraneous mechanical components required, the better for increased density and overall performance. “Sprung heat sinks” have a larger tolerance loop, which can result in varying pressure on the die depending upon the size of the tolerance loop and spring rate of the springs used. This can be problematic when the tolerances result in forces too low for good phase change TIM flow, or too high, which can result in die damage or cracked solder balls on the device base. “Table top heat sinks” have a relatively thick thermal interface and are therefore compromised thermally. “Sprung heat sinks” are by design floating assemblies and are therefore compromised in terms of mechanical stability. In some cases, the bare die size is very small. Since one typically wishes to keep the pressure on the die below a goal of ~10 psi, the downward force must be smaller than for other larger die sizes or larger lidded packages. Thermally the solution is good, but the heat sink attachment is not particularly robust against handling and cabling.

The present background is provided as illustrative environmental context only. It will be readily apparent to those of ordinary skill in the art that the concepts and principles of the present disclosure may be implemented in other environmental contexts equally, without limitation.

### SUMMARY

The present disclosure provides a flexible diaphragm vapour chamber heat sink assembly that simplifies a conventional “sprung heat sink” design by hard mounting the vapour chamber heat sink to standoffs on the PCB, and replaces conventional springs which are used to apply force and take up design tolerance with a flexible vapour space within the vapour chamber. The geometry of this vapour space is designed and tuned to a particular application to ensure that the correct flexibility and force is achieved.

Thus, the present disclosure makes use of a flexible vapour space within the vapour chamber itself, which is conventionally a rigid structure designed to not deform. This design instead allows the vapour space to deform in order to apply pressure to the device on the PCB, and take up tolerances in the mechanical design. The present disclosure effectively combines a “table top heat sink” configuration with a thin grease-like or phase-change thermal interface. The dimensions of the flexible portion of the lower vapour chamber “skin” enable it as a useful diaphragm. Partial pillars and/or spring members within the vapour chamber act to prevent over compression. The staggered co-location (without touching) of top pillars and bottom pillars enable skin-to-skin wicking of condensate within the vapour chamber.

In some embodiments, the present disclosure provides a flexible diaphragm vapour chamber heat sink assembly including a vapour chamber heat sink including a rigid outer surface and a flexible device surface coupled together and separated to form a vapour chamber space there between, where the flexible device surface is adapted to be disposed adjacent to and in thermal contact with a device and/or die disposed on a printed circuit board. In some embodiments, the flexible diaphragm vapour chamber heat sink assembly further includes a plurality of partial pillars disposed between and coupled to one of the flexible device surface and the rigid outer surface, where the plurality of partial pillars are disposed within the vapour chamber space proximate the device and/or die and adapted to limit compression of the vapour chamber space when the device and/or die deflect the flexible device surface. In some embodiments, the flexible diaphragm vapour chamber heat sink assembly further includes a plurality of full pillars disposed between and coupled to one or both of the flexible device surface and the rigid outer surface, where the plurality of full pillars are disposed within the vapour chamber space remote from the device and/or die and adapted to prevent compression of the vapour chamber space when the device and/or die deflect the flexible device surface. In some embodiments, the flexible diaphragm vapour chamber heat sink assembly further includes a plurality of spring members disposed between and coupled to one of the flexible device surface and the rigid outer surface, where the plurality of spring members are disposed within the vapour chamber space proximate the device and/or die and adapted to control compression of the vapour chamber space when the device and/or die deflect the flexible device surface. In some embodiments, the surfaces of the spring members include a wick feature, constructed as a mesh, sintered metal, or grooves, and this wick feature serves to provide a path for the condensate to flow between the upper and lower vapour chamber surfaces. In some embodiments, the flexible diaphragm vapour chamber heat sink assembly further includes a plurality of rigid standoffs coupled between the vapour chamber heat sink and the printed circuit board around the device and/or die. In some embodiments, the flexible diaphragm vapour chamber heat sink assembly further includes a plurality of heat sink fins protruding from the rigid outer surface and adapted to communicate heat to an adjacent air flow. In some embodiments, the flexible diaphragm vapour chamber heat sink assembly further includes a cover surface coupled to the plurality of heat sink fins opposite the rigid outer surface. In some embodiments, the flexible diaphragm vapour chamber heat sink assembly further includes a thermal interface material disposed between the flexible device surface and the device and/or die. The flexible diaphragm vapour chamber heat sink assembly further includes a mesh or sintered wick structure for promoting fluid transfer disposed on one or more surfaces within the vapour chamber space. In some embodiments, the rigid surface of the vapour chamber includes one or more flow channels for liquid cooling, making the rigid surface of the vapour chamber a liquid cooled cold plate.

In some embodiments, the present disclosure provides a network node including a printed circuit board, a device and/or die disposed on the printed circuit board, and a vapour chamber heat sink including a rigid outer surface and a flexible device surface coupled together and separated to form a vapour chamber space there between, where the flexible device surface is adapted to be disposed adjacent to and in thermal contact with the device and/or die. In some embodiments, the flexible diaphragm vapour chamber heat sink further includes a plurality of partial pillars disposed between and coupled to one of the flexible device surface and the rigid outer surface, where the plurality of partial pillars are disposed within the vapour chamber space proximate the device and/or die and adapted to limit compression of the vapour chamber space when the device and/or die deflect the flexible device surface. In some embodiments, the flexible diaphragm vapour chamber heat sink further includes a plurality of full pillars disposed between and coupled to one or both of the flexible device surface and the rigid outer surface, where the plurality of full pillars are disposed within the vapour chamber space remote from the device and/or die and adapted to prevent compression of the vapour chamber space when the device and/or die deflect the flexible device surface. In some embodiments, the flexible diaphragm vapour chamber heat sink further includes a plurality of spring members disposed between and coupled to one of the flexible device surface and the rigid outer surface, where the plurality of spring members are disposed within the vapour chamber space proximate the device and/or die and adapted to control compression of the vapour chamber space when the device and/or die deflect the flexible device surface. In some embodiments, the surfaces of the spring members include a wick feature, constructed as a mesh, sintered metal, or grooves, and this wick feature serves to provide a path for the condensate to flow between the upper and lower vapour chamber surfaces. In some embodiments, the flexible diaphragm vapour chamber heat sink further includes a plurality of rigid standoffs coupled between the vapour chamber heat sink and the printed circuit board around the device and/or die. In some embodiments, the flexible diaphragm vapour chamber heat sink further includes a plurality of heat sink fins protruding from the rigid outer surface and adapted to communicate heat to an adjacent air flow. In some embodiments, the flexible diaphragm vapour chamber heat sink further includes a cover surface coupled to the plurality of heat sink fins opposite the rigid outer surface. In some embodiments, the flexible diaphragm vapour chamber heat sink further includes a thermal interface material disposed between the flexible device surface and the device and/or die. The flexible diaphragm vapour chamber heat sink further includes a mesh or sintered wick structure for promoting fluid transfer disposed on one or more surfaces within the vapour chamber space. In some embodiments, the rigid surface of the vapour chamber includes one or more flow channels for liquid cooling, making the rigid surface of the vapour chamber a liquid cooled cold plate.

In some embodiments, the present disclosure provides a flexible diaphragm vapour chamber heat sink method including disposing a vapour chamber heat sink including a rigid outer surface and a flexible device surface coupled together and separated to form a vapour chamber space there between adjacent to and in thermal contact with a device and/or die disposed on a printed circuit board, where a plurality of rigid standoffs are coupled between the vapour chamber heat sink and the printed circuit board around the device and/or die. The vapour chamber heat sink further includes one or more of a plurality of partial pillars disposed between and coupled to one of the flexible device surface and the rigid outer surface, where the plurality of partial pillars are disposed within the vapour chamber space proximate the device and/or die and adapted to limit compression of the vapour chamber space when the device and/or die deflect the flexible device surface, a plurality of full pillars disposed between and coupled to one or both of the flexible device surface and the rigid outer surface, where the plurality of full pillars are disposed within the vapour chamber space remote from the device and/or die and adapted to prevent compression of the vapour chamber space when the device and/or die deflect the flexible device surface, and a plurality of spring members disposed between and coupled to one of the flexible device surface and the rigid outer surface, where the plurality of spring members are disposed within the vapour chamber space proximate the device and/or die and adapted to control compression of the vapour chamber space when the device and/or die deflect the flexible device surface. In some embodiments, the surfaces of the spring members, and the vapour chamber itself, include a wick feature, constructed as a mesh, sintered metal, or grooves, and this wick feature serves to provide a path for the condensate to flow, such as between the upper and lower vapour chamber surfaces via the spring members. In some embodiments, the rigid surface of the vapour chamber includes one or more flow channels for liquid cooling, making the rigid surface of the vapour chamber a liquid cooled cold plate.

It will be readily apparent to those of ordinary skill in the art that aspects and features of the various described embodiments may be included, omitted, or combined as desired in a given application, without limitation.

### BRIEF DESCRIPTION OF THE DRAWINGS

The present disclosure is illustrated and described with reference to the various drawings, in which like reference numbers are used to denote like assembly components/method steps, as appropriate, and in which:

FIG. 1 is a schematic view of one embodiment of the flexible diaphragm vapour chamber heat sink assembly of the present disclosure;

FIG. 2 is a perspective view of one embodiment of the flexible diaphragm vapour chamber heat sink assembly of the present disclosure;

FIG. 3 is a cross-sectional view of one embodiment of the flexible diaphragm vapour chamber heat sink assembly of the present disclosure;

FIG. 4 is a plan view of one embodiment of the flexible diaphragm vapour chamber heat sink assembly of the present disclosure;

FIG. 5 is a partial cross-sectional view of one embodiment of the flexible diaphragm vapour chamber heat sink assembly of the present disclosure;

FIG. 6 is a plan view of another embodiment of the flexible diaphragm vapour chamber heat sink assembly of the present disclosure;

FIG. 7 is a partial cross-sectional view of another embodiment of the flexible diaphragm vapour chamber heat sink assembly of the present disclosure; and

FIG. 8 is a flowchart of one embodiment of the flexible diaphragm vapour chamber heat sink method of the present disclosure.

It will be readily apparent to those of ordinary skill in the art that aspects and features of the various illustrated embodiments may be included, omitted, or combined as desired in a given application, without limitation.

### DETAILED DESCRIPTION

Again, the present disclosure provides a flexible diaphragm vapour chamber heat sink assembly that simplifies a conventional “sprung heat sink” design by hard mounting the vapour chamber heat sink to standoffs on the PCB, and replaces conventional springs which are used to apply force and take up design tolerance with a flexible vapour space within the vapour chamber. The geometry of this vapour space is designed and tuned to a particular application to ensure that the correct flexibility and force is achieved.

Thus, the present disclosure makes use of a flexible vapour space within the vapour chamber itself, which is conventionally a rigid structure designed to not deform. This design instead allows the vapour space to deform in order to apply pressure to the device on the PCB, and take up tolerances in the mechanical design. The present disclosure effectively combines a “table top heat sink” configuration with a thin grease-like or phase-change thermal interface. The dimensions of the flexible portion of the lower vapour chamber “skin” enable it as a useful diaphragm. Partial pillars and/or spring members within the vapour chamber act to prevent over compression. The staggered co-location (without touching) of top pillars and bottom pillars enable skin-to-skin wicking of condensate within the vapour chamber.

In terms of conceptual design, the diaphragm of the vapour chamber; i.e., the intentionally flexible region of the device-facing “skin” of the vapour chamber; may be approximated as a circular diaphragm, and the associated force-displacement relation may be approximated by the small deflection theory for a circular diaphragm under prescribed pressure. Such theory allows one to tailor the geometry of the vapour chamber to satisfy both thermal and mechanical goals. More specifically, the pressure that one desires to see applied to the device by the pedestal of the vapour chamber may be on the order of 10 psi because this value is associated with generally being sufficient to compress a phase change thermal interface while still be under the damage limits of the device and the ball grid array (BGA) construction that sustains the applied pressure. In other words, 10 psi is good for both thermal considerations and mechanical considerations. In practice, the diaphragm need not be circular, and various other shapes are possible, including the rectangular configuration illustrated in the drawings of the present disclosure.

Simultaneously, one may desire to design for roughly 2 mm displacement of the diaphragm, as this displacement takes into consideration the uncertainty in the surface-to-surface position of device top and pedestal bottom, and 2 mm is a reasonable displacement which will: 1) always ensure useful contact pressure between these surfaces, and 2) never result in excessive pressure between these surfaces.

It is found through the small deflection theory that there exist practical combinations of diaphragm size and vapour chamber “skin” thickness such that a useful Force-Displacement characteristics are achieved. For example, a copper vapour chamber with a bottom “skin” thickness of 0.3 mm, and a diaphragm radius of 60 mm (used to approximate a 100×100 mm square), results in a force-displacement characteristic of ~18000 N/m. These are useful parameters for generating ~13 psi on a 20×20 mm device when displaced by 2 mm. Adjustments are fairly easily made from this practical baseline to meet application-specific goals.

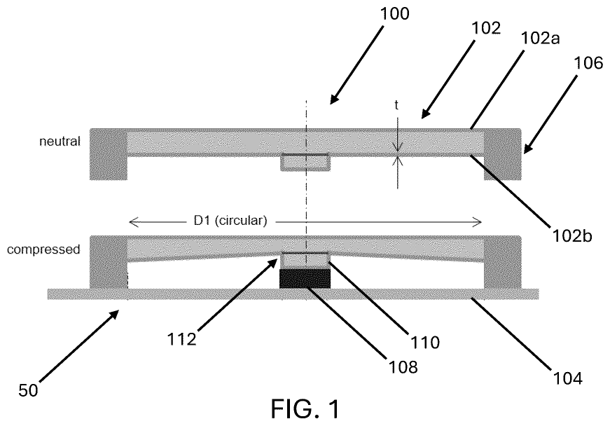

Referring to FIG. 1, conceptually, the flexible diaphragm vapour chamber heat sink assembly 100 of the present disclosure includes a vapour chamber heat sink 102 that is fixedly coupled to a PCB 104 at a plurality of mounting points 106. The vapour chamber heat sink 102 includes a rigid outer surface 102a by which the vapour chamber heat sink 102 is secured to the PCB and a flexible device surface 102b that is disposed adjacent to and deflected by the device 108 and an optional die 110 disposed on the PCB 104. A thin TIM 112, such as a thin grease-like or phase-change TIM, may be disposed between the device 108/die 110 and the flexible device surface 102b of the vapour chamber heat sink 102 to facilitate heat transfer. The rigid outer surface 102a of the vapour chamber heat sink 102 may include a plurality of heat sink fins or the like to facilitate heat transfer to an adjacent cooling air flow. The vapour chamber heat sink 102 is shown in neutral and compressed configurations, with D1 being the circular diameter of the conceptual vapour chamber heat sink 102 and t being the thickness of the flexible device surface 102b. The interior of the vapour chamber heat sink 102 may include a plurality of partial pillars extending from the rigid outer surface 102a or the flexible device surface 102b that limit compression of the vapour chamber heat sink 102 and/or a plurality of spring members that control compression of the vapour chamber heat sink 102. In all embodiments, the flexible diaphragm vapour chamber heat sink assembly 100 of the present disclosure may be utilized in a node or module 50 of a telecommunications or networking system or the like.

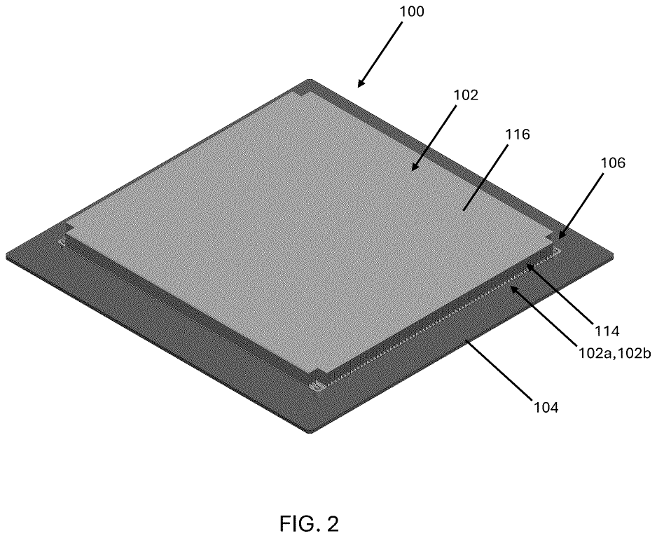

Referring to FIG. 2, in more detail, the flexible diaphragm vapour chamber heat sink assembly 100 of the present disclosure again includes the vapour chamber heat sink 102 that is fixedly coupled to the PCB 104 at the plurality of mounting points 106. The vapour chamber heat sink 102 includes the rigid outer surface 102a by which the vapour chamber heat sink 102 is secured to the PCB and the flexible device surface 102b that is disposed adjacent to and deflected by the device 108 and the optional die 110 disposed on the PCB 104. The components of the vapour chamber heat sink 102 may be manufactured from any thermally conductive metallic material, such as copper or the like. The thin TIM 112, such as a thin grease-like or phase-change TIM, may be disposed between the device 108/die 110 and the flexible device surface 102b of the vapour chamber heat sink 102 to facilitate heat transfer. The rigid outer surface 102a of the vapour chamber heat sink 102 may include the plurality of heat sink fins 114 or the like to facilitate heat transfer to the adjacent cooling air flow. These heatsink fins 114 may be capped by a fin cover surface 116. The interior of the vapour chamber heat sink 102 may include the plurality of partial pillars extending from the rigid outer surface 102a or the flexible device surface 102b that limit compression of the vapour chamber heat sink 102 and/or the plurality of spring members that control compression of the vapour chamber heat sink 102.

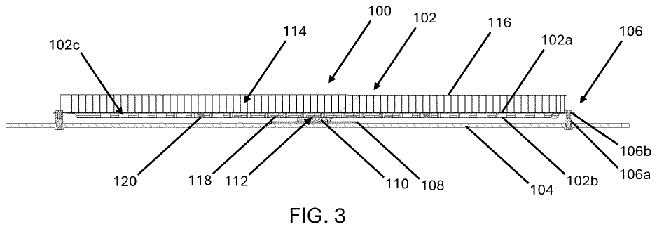

Referring to FIG. 3, in more detail, the flexible diaphragm vapour chamber heat sink assembly 100 of the present disclosure again includes the vapour chamber heat sink 102 that is fixedly coupled to the PCB 104 at the plurality of mounting points 106. Each of the plurality of mounting points 106 includes a fixed height standoff 106a that is affixed to the PCB 104. The vapour chamber heat sink 102 is then secured to the plurality of standoffs 106a using a plurality of mounting screws 106b or the like. It will be readily apparent to those of ordinary skill in the art that other attachment mechanisms may be used equally. The vapour chamber heat sink 102 includes the rigid outer surface 102a (which may include a planar surface and optional side surfaces) by which the vapour chamber heat sink 102 is secured to the PCB and the flexible device surface 102b (which may also include a planar surface and optional side surfaces) that is disposed adjacent to and deflected by the device 108 and the optional die 110 disposed on the PCB 104. The rigid outer surface 102a and the flexible device surface are sealed together to form the vapour chamber 102c there between. The components of the vapour chamber heat sink 102 may again be manufactured from any thermally conductive metallic material, such as copper or the like. The thin TIM 112, such as a thin grease-like or phase-change TIM, may be disposed between the device 108/die 110 and the flexible device surface 102b of the vapour chamber heat sink 102 to facilitate heat transfer. The rigid outer surface 102a of the vapour chamber heat sink 102 may include the plurality of heat sink fins 114 or the like to facilitate heat transfer to the adjacent cooling air flow. These heatsink fins 114 may be capped by a fin cover surface 116. The interior of the vapour chamber heat sink 102 may include the plurality of partial pillars 118 extending from the rigid outer surface 102a or the flexible device surface 102b that limit compression of the vapour chamber heat sink 102 and/or the plurality of spring members that control compression of the vapour chamber heat sink 102. In the embodiment illustrated, the partial pillars 118 each extend from the flexible device surface 102b into the vapour chamber heat sink 102. As described in greater detail below, the partial pillars 118 may be used only in a portion of the vapour chamber heat sink 102 in the vicinity of the device 108 and die 110 to deflect in this region. Full pillars 120 may be used in portions of the vapour chamber heat sink 102 away from the device 108 and die 110 to maintain vapour chamber rigidity in these regions.

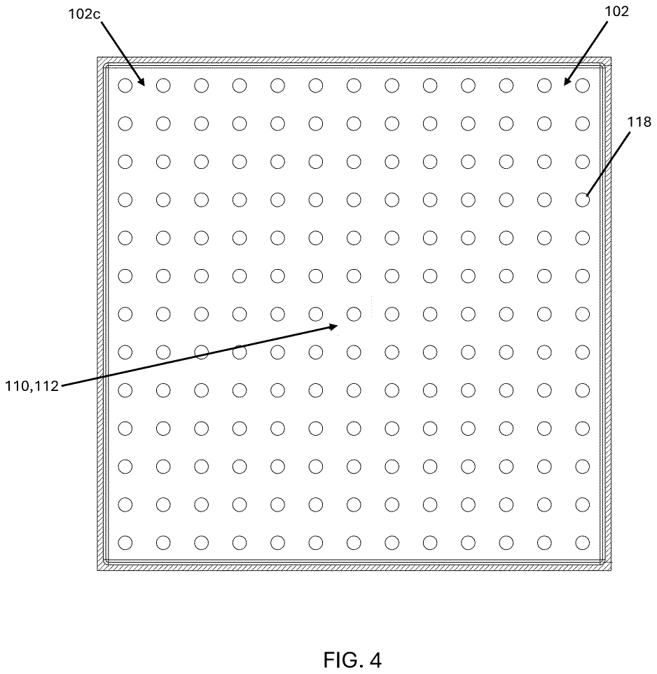

FIG. 4 illustrates the vapour chamber heat sink 102 utilizing the partial pillars 118 in the entirety of the vapour chamber heat sink 102, such that the flexible vapour chamber space 102c is large as compared to the size of the die 110 and TIM 112.

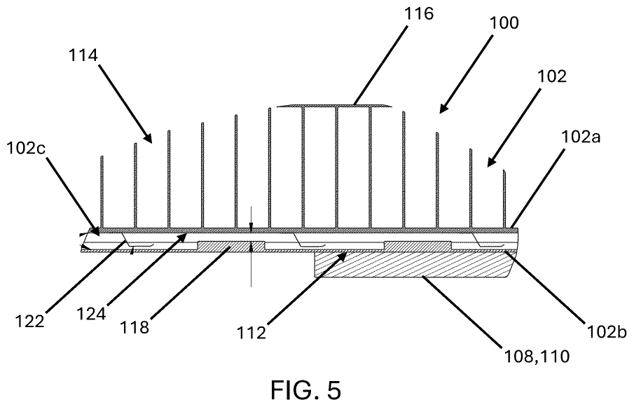

Referring to FIG. 5, in more detail, the flexible diaphragm vapour chamber heat sink assembly 100 of the present disclosure again includes the vapour chamber heat sink 102 that is fixedly coupled to the PCB 104 at the plurality of mounting points 106. Each of the plurality of mounting points 106 includes a fixed height standoff 106a that is affixed to the PCB 104. The vapour chamber heat sink 102 is then secured to the plurality of standoffs 106a using a plurality of mounting screws 106b or the like. It will be readily apparent to those of ordinary skill in the art that other attachment mechanisms may be used equally. The vapour chamber heat sink 102 includes the rigid outer surface 102a (which may include a planar surface and optional side surfaces) by which the vapour chamber heat sink 102 is secured to the PCB and the flexible device surface 102b (which may also include a planar surface and optional side surfaces) that is disposed adjacent to and deflected by the device 108 and the optional die 110 disposed on the PCB 104. The rigid outer surface 102a and the flexible device surface are sealed together to form the vapour chamber 102c there between. The components of the vapour chamber heat sink 102 may again be manufactured from any thermally conductive metallic material, such as copper or the like. The thin TIM 112, such as a thin grease-like or phase-change TIM, may be disposed between the device 108/die 110 and the flexible device surface 102b of the vapour chamber heat sink 102 to facilitate heat transfer. The rigid outer surface 102a of the vapour chamber heat sink 102 may include the plurality of heat sink fins 114 or the like to facilitate heat transfer to the adjacent cooling air flow. These heatsink fins 114 may be capped by a fin cover surface 116. The interior of the vapour chamber heat sink 102 may include the plurality of partial pillars 118 extending from the rigid outer surface 102a or the flexible device surface 102b that limit compression of the vapour chamber heat sink 102 and/or the plurality of spring members 122 that control compression of the vapour chamber heat sink 102. The spring members 122 are leaf springs, coil springs, or the like and extend from the rigid outer surface 102a within the vapour chamber space 102c. In the embodiment illustrated, the partial pillars 118 each extend from the flexible device surface 102b into the vapour chamber space 102c across the entirety of the vapour chamber heat sink 102. Further, any or all internal surfaces of the vapour chamber space 102c, including the surfaces of the pillars 118, 120 and/or spring members 122, may be covered with a mesh, sintered wick structure, or grooves 124 for promoting fluid transfer within the vapour chamber space 102c and for communicating a fluid between and along the rigid outer surface 102a and the flexible device surface 102b of the vapour chamber heat sink 102.

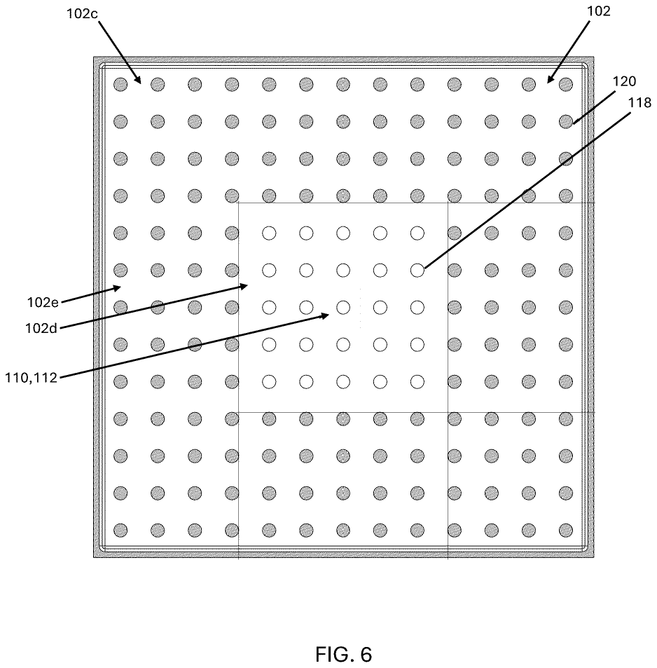

FIG. 6 illustrates the vapour chamber heat sink 102 utilizing the partial pillars 118 in a flexible portion 102d of the vapour chamber heat sink 102 in the vicinity of the die 110 and TIM 112 and the full pillars 120 in a rigid portion 102e of the vapour chamber heat sink 102 remote from the die 110 and TIM 112.

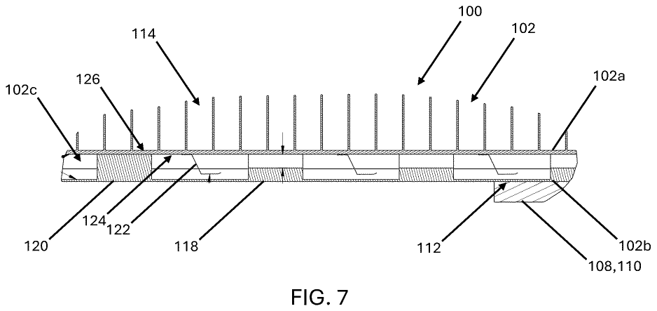

Referring to FIG. 7, in more detail, the flexible diaphragm vapour chamber heat sink assembly 100 of the present disclosure again includes the vapour chamber heat sink 102 that is fixedly coupled to the PCB 104 at the plurality of mounting points 106. Each of the plurality of mounting points 106 includes a fixed height standoff 106a that is affixed to the PCB 104. The vapour chamber heat sink 102 is then secured to the plurality of standoffs 106a using a plurality of mounting screws 106b or the like. It will be readily apparent to those of ordinary skill in the art that other attachment mechanisms may be used equally. The vapour chamber heat sink 102 includes the rigid outer surface 102a (which may include a planar surface and optional side surfaces) by which the vapour chamber heat sink 102 is secured to the PCB and the flexible device surface 102b (which may also include a planar surface and optional side surfaces) that is disposed adjacent to and deflected by the device 108 and the optional die 110 disposed on the PCB 104. The rigid outer surface 102a and the flexible device surface are sealed together to form the vapour chamber 102c there between. The components of the vapour chamber heat sink 102 may again be manufactured from any thermally conductive metallic material, such as copper or the like. The thin TIM 112, such as a thin grease-like or phase-change TIM, may be disposed between the device 108/die 110 and the flexible device surface 102b of the vapour chamber heat sink 102 to facilitate heat transfer. The rigid outer surface 102a of the vapour chamber heat sink 102 may include the plurality of heat sink fins 114 or the like to facilitate heat transfer to the adjacent cooling air flow. These heatsink fins 114 may be capped by a fin cover surface 116. The interior of the vapour chamber heat sink 102 may include the plurality of partial pillars 118 extending from the rigid outer surface 102a or the flexible device surface 102b that limit compression of the vapour chamber heat sink 102 and/or the plurality of spring members 122 that control compression of the vapour chamber heat sink 102. The spring members 122 are leaf springs, coil springs, or the like and extend from the rigid outer surface 102a within the vapour chamber space 102c. In the embodiment illustrated, the partial pillars 118 each extend from the flexible device surface 102b into the vapour chamber space 102c across the portion of the vapour chamber heat sink 102 proximate the device 108 and die 110. The full pillars 120 each extend between the flexible device surface 102b and the rigid outer surface 102a through the vapour chamber space 102c across the portion of the vapour chamber heat sink 102 remote from the device 108 and die 110. Further, any or all internal surfaces of the vapour chamber space 102c may be covered with a mesh or sintered wick structure 124 for promoting fluid transfer within the vapour chamber space 102c. It should be noted that a flow channel 126 may be embedded in the rigid outer surface 102a and adapted for communicating a cooling liquid through the rigid outer surface 102a, such that the rigid outer surface 102a acts as a liquid cooled cold plate heat sunk, in addition to acting as part of the vapour chamber heat sink 102.

Thus, the flexible diaphragm vapour chamber heat sink assembly of the present disclosure provides decreased design complexity, increased design performance, and helps to maintain consistency between assembly batches. Circuit assemblies are more mechanically robust as the circuit assemblies include heat sinks hard-mounted to the PCB (rather than floating on sprung sub-assemblies) with two associated benefits: 1) highly stable heat sink attachment, resilient against movement from general handling and/or pressure from on-board semi-flex cables, and 2) no-risk strategy when considering mechanical qualification tests like packaged drop, unpackaged drop, transport vibration, and seismic.

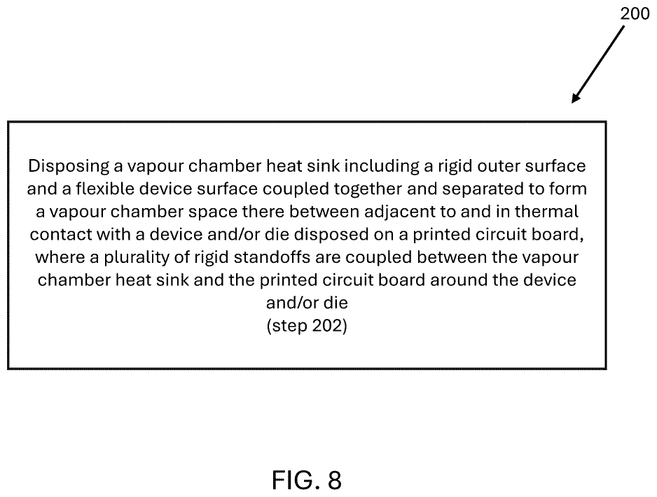

Referring to FIG. 8, the flexible diaphragm vapour chamber heat sink method 200 of the present disclosure includes disposing a vapour chamber heat sink including a rigid outer surface and a flexible device surface coupled together and separated to form a vapour chamber space there between adjacent to and in thermal contact with a device and/or die disposed on a printed circuit board, where a plurality of rigid standoffs are coupled between the vapour chamber heat sink and the printed circuit board around the device and/or die (step 202). The vapour chamber heat sink further includes one or more of a plurality of partial pillars disposed between and coupled to one of the flexible device surface and the rigid outer surface, where the plurality of partial pillars are disposed within the vapour chamber space proximate the device and/or die and adapted to limit compression of the vapour chamber space when the device and/or die deflect the flexible device surface, a plurality of full pillars disposed between and coupled to one or both of the flexible device surface and the rigid outer surface, where the plurality of full pillars are disposed within the vapour chamber space remote from the device and/or die and adapted to prevent compression of the vapour chamber space when the device and/or die deflect the flexible device surface, and a plurality of spring members disposed between and coupled to one of the flexible device surface and the rigid outer surface, where the plurality of spring members are disposed within the vapour chamber space proximate the device and/or die and adapted to control compression of the vapour chamber space when the device and/or die deflect the flexible device surface.

Although the present disclosure is illustrated and described with reference to illustrative embodiments and examples, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following non-limiting claims for all purposes.

What is claimed is:

1. A flexible diaphragm vapour chamber heat sink assembly comprising
a vapour chamber heat sink comprising a rigid outer surface and a flexible device surface coupled together and separated to form a vapour chamber space there between, wherein the flexible device surface is adapted to be disposed adjacent to and in thermal contact with a device and/or die disposed on a printed circuit board.

2. The flexible diaphragm vapour chamber heat sink assembly of claim 1, further comprising a plurality of partial pillars disposed between and coupled to one of the flexible device surface and the rigid outer surface, wherein the plurality of partial pillars are disposed within the vapour chamber space proximate the device and/or die and adapted to limit compression of the vapour chamber space when the device and/or die deflect the flexible device surface.

3. The flexible diaphragm vapour chamber heat sink assembly of claim 1, further comprising a plurality of full pillars disposed between and coupled to one or both of the flexible device surface and the rigid outer surface, wherein the plurality of full pillars are disposed within the vapour chamber space remote from the device and/or die and adapted to prevent compression of the vapour chamber space when the device and/or die deflect the flexible device surface.

4. The flexible diaphragm vapour chamber heat sink assembly of claim 1, further comprising a plurality of spring members disposed between and coupled to one of the flexible device surface and the rigid outer surface, wherein the plurality of spring members are disposed within the vapour chamber space proximate the device and/or die and adapted to control compression of the vapour chamber space when the device and/or die deflect the flexible device surface.

5. The flexible diaphragm vapour chamber heat sink assembly of claim 1, further comprising a plurality of rigid standoffs coupled between the vapour chamber heat sink and the printed circuit board around the device and/or die.

6. The flexible diaphragm vapour chamber heat sink assembly of claim 1, further comprising one or more of:
a plurality of heat sink fins protruding from the rigid outer surface and adapted to communicate heat to an adjacent air flow, and
a flow channel embedded in the rigid outer surface and adapted for communicating a cooling liquid through the rigid outer surface.

7. The flexible diaphragm vapour chamber heat sink assembly of claim 6, further comprising a cover surface coupled to the plurality of heat sink fins opposite the rigid outer surface.

8. The flexible diaphragm vapour chamber heat sink assembly of claim 1, further comprising a thermal interface material disposed between the flexible device surface and the device and/or die.

9. The flexible diaphragm vapour chamber heat sink assembly of claim 1, further comprising a mesh, sintered wick structure, or grooves for promoting fluid transfer disposed on one or more component surfaces within the vapour chamber space for communicating a fluid between and along the rigid outer surface and the flexible device surface of the vapour chamber heat sink.

10. A network node comprising
a printed circuit board,
a device and/or die disposed on the printed circuit board, and
a vapour chamber heat sink comprising a rigid outer surface and a flexible device surface coupled together and separated to form a vapour chamber space there between, wherein the flexible device surface is adapted to be disposed adjacent to and in thermal contact with the device and/or die.

11. The network node of claim 10, further comprising a plurality of partial pillars disposed between and coupled to one of the flexible device surface and the rigid outer surface, wherein the plurality of partial pillars are disposed within the vapour chamber space proximate the device and/or die and adapted to limit compression of the vapour chamber space when the device and/or die deflect the flexible device surface.

12. The network node of claim 10, further comprising a plurality of full pillars disposed between and coupled to one or both of the flexible device surface and the rigid outer surface, wherein the plurality of full pillars are disposed within the vapour chamber space remote from the device and/or die and adapted to prevent compression of the vapour chamber space when the device and/or die deflect the flexible device surface.

13. The network node of claim 10, further comprising a plurality of spring members disposed between and coupled to one of the flexible device surface and the rigid outer surface, wherein the plurality of spring members are disposed within the vapour chamber space proximate the device and/or die and adapted to control compression of the vapour chamber space when the device and/or die deflect the flexible device surface.

14. The network node of claim 10, further comprising a plurality of rigid standoffs coupled between the vapour chamber heat sink and the printed circuit board around the device and/or die.

15. The network node of claim 10, further comprising one or more of:
a plurality of heat sink fins protruding from the rigid outer surface and adapted to communicate heat to an adjacent air flow, and
a flow channel embedded in the rigid outer surface and adapted for communicating a cooling liquid through the rigid outer surface.

16. The network node of claim 10, further comprising a cover surface coupled to the plurality of heat sink fins opposite the rigid outer surface.

17. The network node of claim 10, further comprising a thermal interface material disposed between the flexible device surface and the device and/or die.

18. The network node of claim 10, further comprising a mesh, sintered wick structure, or grooves for promoting fluid transfer disposed on one or more component surfaces within the vapour chamber space for communicating a fluid between and along the rigid outer surface and the flexible device surface of the vapour chamber heat sink.

19. A flexible diaphragm vapour chamber heat sink method comprising
disposing a vapour chamber heat sink comprising a rigid outer surface and a flexible device surface coupled together and separated to form a vapour chamber space there between adjacent to and in thermal contact with a device and/or die disposed on a printed circuit board, wherein a plurality of rigid standoffs are coupled between the vapour chamber heat sink and the printed circuit board around the device and/or die.

20. The flexible diaphragm vapour chamber heat sink method of claim 19, wherein the vapour chamber heat sink further comprises one or more of
a plurality of partial pillars disposed between and coupled to one of the flexible device surface and the rigid outer surface, wherein the plurality of partial pillars are disposed within the vapour chamber space proximate the device and/or die and adapted to limit compression of the vapour chamber space when the device and/or die deflect the flexible device surface,
a plurality of full pillars disposed between and coupled to one or both of the flexible device surface and the rigid outer surface, wherein the plurality of full pillars are disposed within the vapour chamber space remote from the device and/or die and adapted to prevent compression of the vapour chamber space when the device and/or die deflect the flexible device surface, and
a plurality of spring members disposed between and coupled to one of the flexible device surface and the rigid outer surface, wherein the plurality of spring members are disposed within the vapour chamber space proximate the device and/or die and adapted to control compression of the vapour chamber space when the device and/or die deflect the flexible device surface.
